(19) United States
(12) Patent Application Publication
(10) Pub. No.: US 2008/0157774 A1
(43) Pub. Date: Jul. 3, 2008

(54) Method For Testing An Electronic Circuit For Driving A Dc-Motor

(75) Inventor: Bo Vestergard Jensen, Kobenhavn (DK)

Correspondence Address: NOVO NORDISK, INC.;INTELLECTUAL PROPERTY DEPARTMENT, 100 COLLEGE ROAD WEST, PRINCETON, NJ, 08540, US

(73) Assignee: Novo Nordisk A/S, Bagsvaerde (DK)

(21) Appl. No.: 11/816,554

(22) PCT Filed: Feb. 14, 2006
(86) PCT No.: PCT/DK06/00084

§ 371 Date: Oct. 16, 2007

(30) Foreign Application Priority Data
Feb. 23, 2005 (DK) PA 2005 00273

(51) Int. Cl. G01R 31/327

(52) U.S. Cl. 324/415

(57) ABSTRACT

The present invention relates to a method for testing an electronic circuit comprising a plurality of switching elements arranged in a H-bridge configuration, the electronic circuit being adapted to drive an associated DC-motor operatively connected to the H-bridge, the DC-motor being adapted to move an associated piston rod in an injection device, the method comprising the steps of providing a test signal to the electronic circuit, and measuring a value of a return signal in response to the provided test signal and determining whether the value of the return signal is in agreement with an expected value, the providing of the test signal and the measuring of the return signal being performed while one or more switching elements is/are switched off.

### FIELD OF THE INVENTION

The present invention relates to a method for testing an electronic circuit driving a DC-motor. In particular, the present invention relates to a method for testing a H-bridge for driving a DC-motor operatively connected to a piston rod in an injection device.

### BACKGROUND OF THE INVENTION

In a battery powered medical dispensing system, where the dispensing mechanism is driven by a DC motor and controlled by a microprocessor, the DC motor is often controlled via an H-bridge transistor configuration. When using an H-bridge it is possible to reverse the motor direction and control the voltage applied to the motor by Pulse Width Modulating (PWM) the H-bridge transistors. The PWM is controlled by the microprocessor system.

U.S. Pat. No. 5,642,247 discloses an automatic fault monitoring system applying an H-bridge circuit having active devices, preferably field effect transistors, in each arm of the bridge. A motor is connected to the H-bridge. Currents and voltages are sensed in each arm as different operating conditions represented by input control signals. Fault detection logic is responsive to currents and voltages in the arms and leg of the bridge and provides outputs indicative of over-current fault conditions in the arm and open circuit fault conditions in the leg. Fault detection control logic analyzes the input control signals and also applies them to change the state of the transistors in the H-bridge.

It is a disadvantage of the system disclosed in U.S. Pat. No. 5,642,247 that the motor connected to the legs of the H-bridge needs to be operated in order for the automatic fault monitoring system of U.S. Pat. No. 5,642,247 to operate properly.

U.S. Pat. No. 6,147,545 discloses a bridge circuit applying active feedback to control drive phase turn on to substantially eliminate shoot-through current. A voltage sensor senses H-bridge transistor voltage turn off levels and causes a control circuit to latch which causes an enable circuit to allow the next phase of H-bridge transistor turn on. A critical aspect of the circuit suggested in U.S. Pat. No. 6,147,545 is to ensure that all H-bridge transistors are switched off before the enable circuit allows the next phase to turn any H-bridge transistors on. Again, the motor needs to be operated in order for the circuit of U.S. Pat. No. 6,147,545 to operate properly.

US 2004/0189229 discloses a fully protected H-bridge for a DC motor, The H-bridge consists of two high side MOSFETs and a control and logic IC on a first conductive heat sink all within a first package and two discrete low side MOSFETs. The entire H-bridge is controlled by the IC. Shoot thru protection is provided for each leg, and a PMW soft start sequence is provided through the control of the low side MOSFETs. Protective circuits are provided for short circuit current and over current conditions. Sleep mode and braking/non braking control is also provided. US 2004/0189229 fails to disclose a test sequence applicable when the motor is at rest.

In order to increase safety, the control of an H-bridge in a dispensing device is often split between to independent microprocessor systems. Such systems are known as two channel safety systems. Before dispensing of a medicament an agreement between the independent microprocessor systems must be reached. Both systems are able to interrupt an initiated dispensing if an error is detected during dispensing. However, if an error occurs in one of the transistors or the circuits controlling them it is not possible to control the motor in a controllable manner.

Therefore, there is a need for a method for verifying that an H-bridge configuration in a dispensing device is fully functional before dispensing of a medicament is initiated, i.e. before the switches of the H-bridge is activated.

Thus, it is an object of the present invention to provide a test procedure or test method for testing or verifying that the H-bridge for driving a motor in a dispensing device, such as an injection device, is fully functional.

### SUMMARY OF THE INVENTION

The major advantage of the present invention is that errors in the H-bridge transistor configuration can be identified before dispensing of a set dose of medicine is initiated. The test according to the present invention is performed via a relative simple electrical circuit and without any movement of the motor and the piston rod. At the same time the H-bridge transistor configuration is tested, the motor connections are also tested. When using a dual microprocessor safety system the H-bridge test sequence is coordinated between the two microprocessor systems.

In a first aspect, the present invention relates to a method for testing an electronic circuit comprising a plurality of switching elements arranged in a H-bridge configuration, the electronic circuit being adapted to drive an associated DC-motor operatively connected to the H-bridge, the DC-motor being adapted to move an associated piston rod in an injection device, the method comprising the steps of
providing, via a first impedance element, a test signal to the electronic circuit, and
measuring, via a second impedance element, a value of a return signal in response to the provided test signal and determining whether the value of the return signal is in agreement with an expected value, the providing of the test signal and the measuring of the return signal being performed while one or more switching elements is/are switched off.

The impedance element may be a resistor, a capacitor or an inductor. In case the impedance element is a capacitor or an inductor, the test signal may be provided as a pulse or as an AC signal. In case the impedance element is a resistor, the test signal may be provided as a digital signal being processed by a main processor, the digital test signal thus having one of two values; logic high or logic low. The switching elements may be a transistor or any kind of similar device.

Typically, the H-bridge may comprise a pair of main switching elements being adapted to be switched on and off by a main processor, and a pair of safe switching elements being adapted to be switched on and off by a safety processor. A forward main switching element and a forward safe switching element may cooperate to drive or rotate the DC-motor in a forward direction. Similarly, a reverse main switching element and a reverse safe switching element may cooperate to drive or rotate the DC-motor in a reverse direction. The safe switching elements are positioned between a power source, such as a battery, and the terminals on the DC-motor, whereas the main switching elements are positioned between the terminals on the DC-motor and ground. The configuration of the H-bridge to be tested may be seen in FIG. 1.

In a preferred embodiment the method according to the present invention comprises nine steps. However, some of the steps are optional and may be omitted from the method according to the present invention.

A first step according to the present invention may comprise the step of switching all switching elements off and applying the test signal from the main processor and measuring the value of the return signal while all switching elements are switched off. In this first step the applied test signal may be logic high. If the return signal is measured to be logic low, an error signal may be generated and the method may be stopped because an error has been detected in the H-bridge. Such error could be that one or more switching elements is/are switched on.

If the return signal is measured to be logic high, a second step of the method may be initiated. This second step implies that a subsequent logic low test signal may be applied. If the return signal is measured to be logic high, an error signal may be generated and the method may be stopped and no further steps are initiated.

If the return signal is measured to be logic low, a third step of the method may be initiated whereby a subsequent logic high test signal may be applied. Furthermore, a first switching element may be switched on. This first switching element may be the main forward switching element. Again, if the return signal is measured to be logic high, an error signal may be generated and the method may be stopped.

If the return signal is measured to be logic low, a subsequent logic high test signal may be applied, and a second switching element (for example the main reverse switching element) may be switched on whereby a fourth step of the present invention may be initiated. If the return signal is measured to be logic high, an error signal may be generated and the method may be stopped.

If the return signal is measured to be logic low, an optionally fifth step of the method according to the present invention may be initiated. In this optionally fifth step a logic high test signal may be applied, and all switching elements are switched off. If the return signal is measured to be logic low, an error signal may be generated and the method may be stopped.

If the return signal is measured to be logic high, a subsequent logic low test signal may be applied as part of a sixth step, and a third switching element (for example the safe forward switching element) may be switched on. If the return signal is measured to be logic low, an error signal may be generated and the method may be stopped.

If the return signal is measured to be logic high, an optionally seventh step of the method may be initiated. This implies that a subsequent logic low test signal may be applied, and all switching elements are switched off. If the return signal is measured to be logic high, an error signal may be generated and the method may be stopped.

If the return signal is measured to be logic low, an eighth step may be initiated which implies that a subsequent logic low test signal may be applied, and a fourth switching element (for example the safe reverse switching element) may be switched on. If the return signal is measured to be logic low, an error signal may be generated and the method may be stopped.

If the return signal is measured to be logic high, an optionally ninth step may be initiated whereby a subsequent logic low test signal may be applied and all switching elements are switched off. If the return signal is measured to be logic high, an error signal may be generated and the method may be stopped. On the contrary, if the return signal is measured to be logic low, the electronic circuit comprising the plurality of switching elements arranged in a H-bridge configuration is ready for use.

In a second aspect, the present invention relates to a method for testing an electronic circuit comprising a plurality of switching elements arranged in a H-bridge configuration, the electronic circuit being adapted to drive an associated DC-motor operatively connected to the H-bridge, the DC-motor being adapted to move an associated piston rod in an injection device, the method comprising the steps of
providing, via a first impedance element, a test signal to the electronic circuit, and
measuring, via a second impedance element, and determining a value of a return signal in response to the provided test signal, the providing of the test signal and the measuring of the return signal being performed while
   all switching elements are switched off, or while
   at least one switching element is switched on.

Preferably, only one switching element is switched on at the time. Thus and preferably, the test signal is applied and the return signal is measured while all switching elements are switched off, or while a single switching element is switched on.

In a third aspect, the present invention relates to an apparatus for performing the method according to the first or second aspects, the apparatus comprising
an electronic circuit comprising a plurality of switching elements arranged in a H-bridge configuration, the electronic circuit being adapted to drive an associated DC-motor operatively connected to the H-bridge, the DC-motor being adapted to move an associated piston rod in an injection device, and
a first and a second processor, each processor being adapted to control a plurality of switching element, the first processor further being adapted to provide, via a first impedance element, a test signal to the H-bridge, the first processor further being adapted to receive and process, via a second impedance element, a return signal from the H-bridge, the return signal being indicative of the status of the H-bridge.

The apparatus may further comprise a battery for providing power to the H-bridge and for supplying the first and second processors.

In a fourth aspect, the present invention relates to an injection device for injecting a set dose of medicament from an ampoule, the injection device comprising an apparatus according to the third aspect. The medicament to be injected may for example be insulin.

### BRIEF DESCRIPTION OF THE DRAWINGS

The present invention will now be described in further details with reference to the accompanying figures, wherein

FIG. 1 shows the H-bridge to be tested, and

FIG. 2 shows a flow chart illustrating the method according to the present invention.

While the invention is susceptible to various modifications and alternative forms, specific embodiments have been shown by way of example in the drawings and will be described in detail herein. It should be understood, however, that the invention is not intended to be limited to the particular forms disclosed. Rather, the invention is to cover all modifications, equivalents, and alternatives falling within the spirit and scope of the invention as defined by the appended claims.

### DETAILED DESCRIPTION OF THE INVENTION

In its most general aspect the present invention relates to a method for testing a H-bridge transistor configuration. According to the method of the present invention the H-bridge transistor configuration is tested by applying a voltage (test signal) via a large impedance element to the plus terminal of the DC-motor. If the H-bridge is fully functional a corresponding voltage (return signal) should be present when measured through a large impedance element connected to the DC-motor minus terminal. When one of the transistors in the H-bridge is activated (switched on) the value of the return signal will change.

The impedance elements can be capacitors, inductors or resistors. For simplicity reasons the method and apparatus according to the present invention will now be described as if the impedance elements are implemented as resistors. For obvious reasons, the test signal will be some sort of alternating signal, such as a pulse or an AC-signal, if the impedance elements are implemented as capacitors or inductors. In case of resistors, the resistance of the resistors connected to the terminals of the DC-motor must be large (×1000) compared to the internal resistance of the DC-motor. By applying the voltage (test signal) and activating the transistors of the H-bridge one at the time and in a predefined sequence the functionality of the H-bridge transistor configuration can be fully tested.

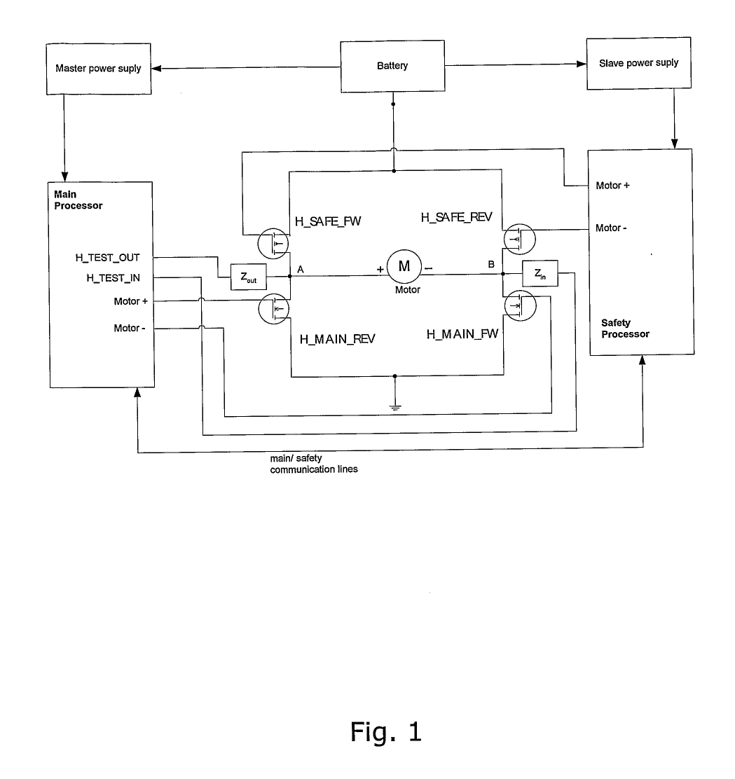

The H-bridge transistor configuration is shown in FIG. 1 with various other components. As seen, the system comprises a main and a safety power supply, a battery, a main and a safety processor and the four transistor H-bridge configuration.

The H-bridge test output (H_TEST_OUT) and test input (H_TEST_IN) signals are controlled by the main processor as digital output and digital input signals. The safety processor only activates or deactivates transistors. When the H-bridge test is performed test point A is pulled to either logic high or logic low via “H_TEST_OUT”. The main processor measures the voltage potential at test point B via H_TEST_IN. Obviously, the test input signal can be either logic high or logic low.

The working principle is based on that there will only flow a current through external resistor Z_{OUT} as long as one of the transistors is on because H_TEST_IN is high impedance. When H_TEST_IN has high impedance the potential at test point B is equal to H_TEST_IN. When for instance:
H_SAFE_FW is on and the H_TEST_OUT is low, there will flow a current through Z_{OUT} and H_SAFE_FW from H_TEST_OUT towards the battery. This leads to a High potential at B.
H_MAIN_FW is on and H_TEST_OUT is high, there will flow a current through Z_{OUT}, the motor and H_MAIN_FW towards ground from H_TEST_OUT. This leads to a low potential at B. During the test the motor can be considered to act as a short circuit.

The method according to the present invention is implemented as a separate test which is performed just before dispensing starts in order to check that the H-bridge is fully functional.

The test itself may comprise up to 9 separate steps—these steps are illustrated in Table 1. The expected values of H_TEST_IN are also given in Table 1 for the various steps. Obviously, the expected values of H_TEST_IN depend on the values of H_TEST_OUT and whether a given transistor is switched on or of. The different transistors are referred to as H_MAIN_FW, H_MAIN_REV, H_SAFE_FW AND H_SAFE_REV.

The main and safety processors communicate via the main/safety communication link. Via this communication link the main processor informs the safety processor when the safety processor should activate or deactivate the transistors H_SAFE_FW and H_SAFE_REV.

As seen from Table 1 only one transistor is switched on at the time. Otherwise the motor could be activated or the battery may even be short circuited.

The method for testing the H-bridge preferably comprises nine steps. However, as will be shown in the following, three of these steps may be omitted. The steps to be performed according to the present invention are as follow:

Step 1: As a first step all switching elements are switched off. A test signal is applied from the main processor and the value of the return signal is measured while all switching elements are switched off. In this first step the applied test signal is logic high. If the return signal is logic low, an error signal is generated and the method may be stopped because an error has been detected in the H-bridge. Such error could be that for example the H_MAIN_RW is switched on whereby the point B is short circuited to ground.

Step 2: If the return signal is measured to be logic high, a second step is initiated. This second step implies that a subsequent logic low test signal is applied. If the return signal is measured to be logic high, an error signal is generated and the method is stopped and no further steps are initiated.

Step 3: If the return signal is measured to be logic low, a third step of the method is initiated whereby a subsequent logic high test signal is applied. Furthermore, the main forward switching element is switched on. Again, if the return signal is measured to be logic high, an error signal is generated and the method is stopped.

Step 4: If the return signal is measured to be logic low, a subsequent logic high test signal is applied, and the main reverse switching element is switched on. If the return signal is measured to be logic high, an error signal is generated and the method is stopped.

Step 5 (optional): If the return signal is measured to be logic low, an optionally fifth step of the method according to the present invention is initiated. In this optionally fifth step a logic high test signal is applied, and all switching elements are switched off. If the return signal is measured to be logic low, an error signal is generated and the method is stopped.

Step 6: If the return signal is measured to be logic high, a subsequent logic low test signal is applied as part of a sixth step, and the safe forward switching element is switched on. If the return signal is measured to be logic low, an error signal is generated and the method is stopped.

Step 7 (optional): If the return signal is measured to be logic high, an optionally seventh step of the method is initiated. This implies that a subsequent logic low test signal is applied, and all switching elements are switched off. If the return signal is measured to be logic high, an error signal is generated and the method is stopped.

Step 8: If the return signal is measured to be logic low, an eighth step is initiated which implies that a subsequent logic low test signal is applied, and the safe reverse switching element is switched on. If the return signal is measured to be logic low, an error signal is generated and the method is stopped.

Step 9 (optional): If the return signal is measured to be logic high, an optionally ninth step is initiated whereby a subsequent logic low test signal is applied and all switching elements are switched off. If the return signal is measured to be logic high, an error signal is generated and the method is stopped. On the contrary, if the return signal is measured to be logic low, the electronic circuit comprising the plurality of switching elements arranged in a H-bridge configuration is ready for use.

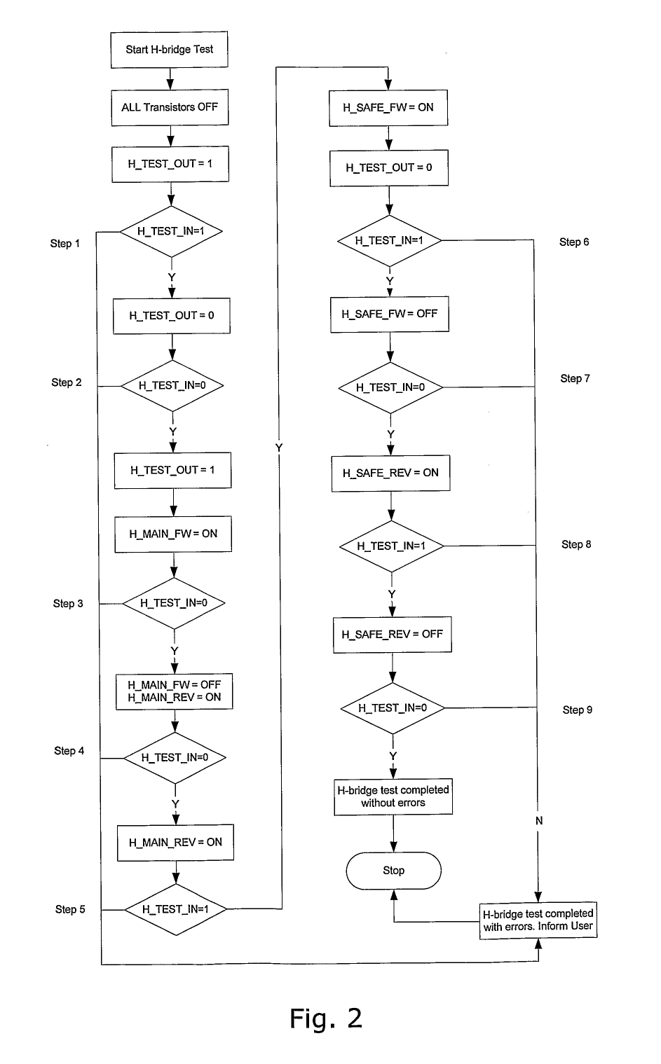

FIG. 2 shows the information presented in Table 1 in the form of a flow chart. Starting from above all transistors all switched off and H_TEST_OUT is set high. If H_TEST_IN is high then H_TEST_OUT is set low. If H_TEST_IN is different from high the H-bridge test is completed with error and the user is informed accordingly.

With H_TEST_OUT being low H_TEST_IN is expected to be low as well. If this is the case H_TEST_OUT is set high and H_MAIN_FW is switched on. If H_TEST_IN is different from low the H-bridge test is completed with error and the user is informed accordingly.

With H_TEST_OUT being high and H_MAIN_FW being switched on H_TEST_IN is expected to be low. If this is the case H_MAIN_FW is switched off and H_MAIN_REV is switched on. If H_TEST_IN is different from low the H-bridge test is completed with error and the user is informed accordingly. It is believed that the remaining steps (steps 4 to 9) shown in FIG. 2 are self explaining.

TABLE 1

| | H_TEST_OUT | H_MAIN_FW | H_MAIN_REV | H_SAFE_FW | H_SAFE_REV | H_TEST_IN | Comment |
|---|---|---|---|---|---|---|---|
| 1 | 1 | OFF | OFF | OFF | OFF | 1 | All off checking |
| | | | | | | | for floating |
| | | | | | | | motor. Pull to |
| | | | | | | | high level |
| 2 | 0 | OFF | OFF | OFF | OFF | 0 | All off checking |
| | | | | | | | for floating |
| | | | | | | | motor. Pull to |
| | | | | | | | low level |
| 3 | 1 | ON | OFF | OFF | OFF | 0 | Pull to high |
| | | | | | | | level |
| | | | | | | | H_MAIN_FW |
| | | | | | | | on |
| 4 | 1 | OFF | ON | OFF | OFF | 0 | H_MAIN_REV |
| | | | | | | | On |
| 5 | 1 | OFF | OFF | OFF | OFF | 1 | All off checking |
| | | | | | | | for floating |
| | | | | | | | motor |
| 6 | 0 | OFF | OFF | ON | OFF | 1 | Pull to low |
| | | | | | | | level |
| | | | | | | | H_SAFE_FWON |
| 7 | 0 | OFF | OFF | OFF | OFF | 0 | H_SAFE_FW |
| | | | | | | | OFF |
| 8 | 0 | OFF | OFF | OFF | ON | 1 | H_SAFE_REV |
| | | | | | | | ON |
| 9 | 0 | OFF | OFF | OFF | OFF | 0 | ALL OFF |

1. A method for testing an electronic circuit comprising a plurality of switching elements arranged in a H-bridge configuration, the electronic circuit being adapted to drive an associated DC-motor operatively connected to the H-bridge, the DC-motor being adapted to move an associated piston rod in an injection device, the method comprising:
providing, via a first impedance element, a test signal to the electronic circuit, and
measuring, via a second impedance element, a value of a return signal in response to the provided test signal and determining whether the value of the return signal is in agreement with an expected value, the providing of the test signal and the measuring of the return signal being performed while one or more switching elements is/are switched off.

2. The method according to claim 1, wherein the test signal is provided as a digital signal being processed by a main processor, the digital test signal having one of two values; logic high or logic low
wherein the test signal is provided as a pulsed signal or an AC signal being processed by a main processor.

3. The method according to claim 1, wherein the H-bridge comprises a pair of main switching elements being adapted to be switched on and off by a main processor, and a pair of safe switching elements being adapted to be switched on and off by a safety processor.

4. The method according to claim 3, wherein a forward main switching element and a forward safe switching element cooperate to drive or rotate the DC-motor in a forward direction.

5. The method according to claim 3, wherein a reverse main switching element and a reverse safe switching element cooperate to drive or rotate the DC-motor in a reverse direction.

6. The method according to claim 5, further comprising switching all switching elements off and applying the test signal and measuring the value of the return signal while all switching elements are switched off.

7. The method according to claim 6, where the applied test signal is logic high.

8. The method according to claim 7, wherein, if the return signal is measured to be logic low, an error signal is generated and the method is stopped.

9. The method according to claim 7, wherein, if the return signal is measured to be logic high, a subsequent logic low test signal is applied.

10. The method according to claim 9, wherein, if the return signal is measured to be logic high, an error signal is generated and the method is stopped.

11. The method according to claim 9, wherein, if the return signal is measured to be logic low, a subsequent logic high test signal is applied, and a first switching element is switched on.

12. The method according to claim 11, wherein, if the return signal is measured to be logic high, an error signal is generated and the method is stopped.

13. The method according to claim 11, wherein, if the return signal is measured to be logic low, a subsequent logic high test signal is applied, and a second switching element is switched on.

14. The method according to claim 13, wherein, if the return signal is measured to be logic high, an error signal is generated and the method is stopped.

15. The method according to claim 13, wherein, if the return signal is measured to be logic low, a subsequent logic high test signal is applied, and all switching elements are switched off.

16. The method according to claim 15, wherein, if the return signal is measured to be logic low, an error signal is generated and the method is stopped.

17. The method according to claim 15, wherein, if the return signal is measured to be logic high, a subsequent logic low test signal is applied, and a third switching element is switched on.

18. The method according to claim 17, wherein, if the return signal is measured to be logic low, an error signal is generated and the method is stopped.

19. The method according to claim 17, wherein, if the return signal is measured to be logic high, a subsequent logic low test signal is applied, and all switching elements are switched off.

20. The method according to claim 19, wherein, if the return signal is measured to be logic high, an error signal is generated and the method is stopped.

21. The method according to claim 19, wherein, if the return signal is measured to be logic low, a subsequent logic low test signal is applied, and a fourth switching element is switched on.

22. The method according to claim 21, wherein, if the return signal is measured to be logic low, an error signal is generated and the method is stopped.

23. The method according to claim 21, wherein, if the return signal is measured to be logic high, a subsequent logic low test signal is applied, and all switching elements are switched off.

24. The method according to claim 23, wherein, if the return signal is measured to be logic high, an error signal is generated and the method is stopped.

25. The method according to claim 23, wherein, if the return signal is measured to be logic low, the electronic circuit comprising the plurality of switching elements arranged in a H-bridge configuration is ready for use.

26. A method for testing an electronic circuit comprising a plurality of switching elements arranged in a H-bridge configuration, the electronic circuit being adapted to drive an associated DC-motor operatively connected to the H-bridge, the DC-motor being adapted to move an associated piston rod in an injection device, the method comprising:
providing, via a first impedance element, a test signal to the electronic circuit, and
measuring, via a second impedance element, and determining a value of a return signal in response to the provided test signal, the providing of the test signal and the measuring of the return signal being performed while
all switching elements are switched off, or while
at least one switching element is switched on.

27. An apparatus for performing the method according to claim 1, the apparatus comprising:
an electronic circuit comprising a plurality of switching elements arranged in a H-bridge configuration, the electronic circuit being adapted to drive an associated DC-motor operatively connected to the H-bridge, the DC-motor being adapted to move an associated piston rod in an injection device, and
a first and a second processor, each processor being adapted to control a plurality of switching elements, the first processor further being adapted to provide, via a first impedance element, a test signal to the H-bridge, the first processor further being adapted to receive and process, via a second impedance element, a return signal from the H-bridge, the return signal being indicative of the status of the H-bridge.

28. The apparatus according to claim 27, wherein the first and second impedance elements each comprise a resistor, a capacitor or an inductor.

29. The apparatus according to claim 27, further comprising a battery for providing power to the H-bridge and for supplying the first and second processors.

30. An injection device for injecting a set dose of medicament from an ampoule, the injection device comprising an apparatus according to claim 27.
